(19) United States
(12) Patent Application Publication
(10) Pub. No.: US 2023/0361528 A1
(43) Pub. Date: Nov. 9, 2023

(54) METHOD OF DRIVING A LASER DIODE AND CORRESPONDING DEVICE

(71) Applicant: STMicroelectronics (Alps) SAS, Grenoble (FR)

(72) Inventor: Xavier Branca, Sassenage (FR)

(21) Appl. No.: 18/193,190

(22) Filed: Mar. 30, 2023

(30) Foreign Application Priority Data
May 4, 2022 (FR) 2204221

(51) Int. Cl. H01S 5/062; H01S 5/00; H01S 5/06; G01S 7/484; G01S 17/10

(52) U.S. Cl. CPC H01S 5/062; H01S 5/0014; H01S 5/0617; G01S 7/484; G01S 17/10

(57) ABSTRACT

In according with an embodiment, a method for power supplying a laser diode includes: generating a power supply current injected directly into the laser diode; generating a power supply voltage biasing terminals of the laser diode; measuring a temperature in a vicinity of the laser diode; and controlling the power supply current at an adjusted intensity according to the measured temperature or controlling the power supply voltage at an adjusted level according to the measured temperature.

### CROSS-REFERENCE TO RELATED APPLICATIONS

This application claims the benefit of French Patent Application No. 2204221, filed on May 4, 2022, which application is hereby incorporated herein by reference.

### TECHNICAL FIELD

Embodiments of the present disclosure relate generally to an electronic system and method, and, in particular embodiments, to a method of driving a laser diode and a corresponding device.

### BACKGROUND

Time-of-flight sensors typically use lasers as emitters to generate light pulses and a photosensitive sensor to measure the time taken by photons from the light pulses to return to the sensor. The distance between the sensor and the surface on which the photons were reflected is deduced from the time measured. The lasers are typically vertical-cavity surface-emitting laser diodes “VCSEL”, and the photosensitive sensor is typically an array of single-photon avalanche diodes “SPAD”.

VCSEL laser diodes are typically power supplied by forced forward current, because the optical power emitted is linear with respect to the forward current. This being the case, the optical power emitted by a VCSEL laser for a given current varies greatly with temperature, for example by 20% to 40% between 105° C. (degrees Celsius) and −30° C. As VCSEL lasers are power supplied by a current that is not expected to vary with temperature, the effective optical power emitted is highly temperature dependent.

If the power emitted is greater than expected, there is a risk of violating a safety limit of the laser, for example imposed by a standard relating to the application which is made of it, and in addition of causing an overconsumption of energy. On the other hand, if the emitted power is lower than expected, the signal amplitude relative to the ambient optical noise (signal-to-noise ratio) is lower and telemetry performance is degraded.

Conventionally, a compromise is established by giving either a priority to performance or a priority to security. If priority is given to performance, the forward current is fixed to guarantee minimum optical power in a temperature range. At low temperatures, the optical power is greater, reducing the safety margin and consuming additional power. If priority is given to safety, the forward current is fixed to guarantee operation below the safety limit or to limit the power consumed, in the temperature range. At high temperatures, the optical power is smaller and consequently the signal-to-noise ratio is lower and the performance is degraded.

On the other hand, the threshold voltage of the diode (also called forward voltage) for a given current, also varies with the temperature, for example from 15% to 40% between 105° C. and −30° C. The VCSEL laser diode is electrically biased by a voltage generator generating a voltage typically large enough to sustain the highest threshold voltage over a range of temperatures. Consequently, for certain temperatures where the threshold voltage is low, the output voltage of the generator is greater than necessary and generates unnecessary energy consumption.

### SUMMARY

According to one implementation, the intensity of the power supply current is adjusted to generate an optical signal at a target power by the laser diode at the measured temperature. For example, within a power interval imposed for a given application, the target power can be a high power in order to favor performance, even at high temperature, or a moderate power in order to benefit from a reduction in energy consumption at low temperatures.

According to one implementation, the level of the power supply voltage is adjusted for the threshold voltage of the laser diode at the measured temperature.

The threshold voltage of the diode tending to drop with the increasing temperature, the power supply voltage is thus generated at a level adapted for a functional power supply of the diode at low temperature, and at a lower level at high temperature so as not to cause excessive energy consumption.

According to one implementation, the adjusted intensity of the power supply current is obtained by reading a temperature-intensity pair correspondence table specifically established for the laser diode by optical power measurements at different temperatures.

According to one implementation, the adjusted level of the power supply voltage is obtained by reading a temperature-voltage pair correspondence table specifically established for the laser diode, by measuring threshold voltages at different temperatures.

Indeed, although the variations with the temperature of the optical power and the effective threshold voltage of the laser diodes are systematic phenomena, their precise quantifications strongly depend on the practical productions of the diodes and the measurement of the temperature. Thus, the correspondence tables specifically established by measurement in real conditions for each laser diode production allows benefiting from adjustments of the intensity and the voltage, according to the temperature actually measured near the laser diode, in a precise and reliable way.

According to one implementation, the measurement of the temperature comprises thermal conduction in a thermal bridge of the heat in contact with the laser diode towards a temperature measurement point near the laser diode.

This improves the accuracy and relevance of temperature measurement with respect to the behavior of the laser diode, in a simple, efficient and very economical way. Indeed, the temperature can be measured in this respect with a simple and conventional device of the thermistor type (thermal resistance) much cheaper than for example a design of a temperature measurement device integrated into the laser diode.

According to another aspect, provision is made of a time-of-flight distance measurement method, comprising an integration phase comprising an emission of an optical signal by a laser diode power supplied by the method as defined above, a reception of the emitted optical signal after reflection, and a measurement of the time shift in the received signal with respect to the emitted signal.

The improvement in performance of the diode obtained by the method defined above allows, for example, improving the signal-to-noise ratio of the measurement, thanks to a greater power of the optical signal emitted. This can allow to increase the quality and range of the measurement, or to reduce energy consumption, at equal quality, for example by reducing the duration of the integration phase.

According to another aspect, provision is made of a device including a laser diode, a circuit for power supplying the laser diode configured to generate a power supply current capable of being injected directly into the laser diode and to generate a power supply voltage capable of biasing the terminals of the laser diode, and a temperature sensor near the laser diode, the power supply circuit being configured to generate the power supply current at an adjusted intensity according to the measured temperature, and/or to generate the power supply voltage at an adjusted level according to the measured temperature.

According to one embodiment, the power supply circuit is configured to generate the intensity of the power supply current adjusted for a generation of an optical signal at a target power by the laser diode at the measured temperature.

According to one embodiment, the power supply circuit is configured to generate the level of the power supply voltage adjusted for the threshold voltage of the laser diode at the measured temperature.

According to one embodiment, the power supply circuit includes a temperature-intensity pair correspondence table specifically established for the laser diode by optical power measurements at different temperatures, and the power supply circuit is configured to obtain the intensity adjusted for the power supply current by reading the temperature-intensity pair correspondence table.

According to one embodiment, the power supply circuit includes a temperature-voltage pair correspondence table specifically established for the laser diode by electrical characterization measurements at different temperatures, and the power supply circuit is configured to obtain the adjusted level of the power supply voltage by reading the temperature-voltage pair correspondence table.

According to one embodiment, the temperature sensor includes a thermal bridge adapted to thermally conduct the heat in contact with the laser diode towards a measurement point of the temperature sensor near the laser diode.

According to another aspect, provision is also made of a time-of-flight distance sensor, including an emitter incorporating a device as defined above and a receiver, the sensor being configured, during an integration phase, to emit an optical signal with the laser diode, receive the optical signal emitted after reflection with the receiver, and measure a time shift in the received signal with respect to the emitted signal.

### BRIEF DESCRIPTION OF THE DRAWINGS

Other advantages and features of the invention will appear upon examining the detailed description of non-limiting embodiments and implementations and the appended drawings, wherein:

FIG. 1 illustrates a block diagram of a method for supplying power to a laser diode;

FIG. 2 illustrates a schematic of an embodiment device including a laser diode and a circuit for power supplying the laser diode;

FIG. 3 illustrates a schematic view of an electronic circuit board according to an embodiment;

FIG. 4 schematically illustrates a cross-sectional view of an embodiment device; and

FIG. 5 illustrates a table of example values according to an embodiment.

### DETAILED DESCRIPTION OF ILLUSTRATIVE EMBODIMENTS

Some implementations and embodiments of the present invention relate to laser diode power supplies, for example laser diodes integrated with a time-of-flight distance sensor.

Conventional techniques have used a photodiode to measure the emitted power and modulate the forward current accordingly. These techniques are not satisfactory because they generate construction constraints to measure the optical signal, consume energy, and have a relatively high cost. Thus, there is a need to propose techniques for supplying laser diodes, in particular for time-of-flight sensors, advantageously allow embodiments of the present disclosure to benefit from the best performance of the laser diode in terms of power of the optical signal, without risking an overrun of a safety limit, while taking care to limit energy consumption and the costs incurred.

In this respect, provision is made according to one aspect of a method for power supplying a laser diode comprising generating a power supply current injected directly into the laser diode, and generating a power supply voltage biasing the terminals of the laser diode. The method comprises measuring the temperature near the laser diode and controlling the power supply current at an adjusted intensity according to the measured temperature, and/or controlling the power supply voltage at an adjusted level according to the measured temperature.

In other words, it is proposed to dynamically adjust the power supply current of the laser diode according to the effective temperature of the operating conditions of the laser diode. For example, the adjustment can be made so that the performance of the laser diode and/or its power consumption are substantially independent of temperature, which is an advantage in itself for controlling the use of the diode, and further helps to increase the overall performance in terms of power and energy consumption.

Indeed, the adjustment of the level of the power supply voltage allows in particular not generating excess energy consumption at high temperatures, while guaranteeing a functional power supply of the diode at low temperatures, which is advantageous in terms of energy consumption. The adjustment of the intensity of the power supply current can allow in particular not to suffer a loss of optical power at high temperatures while guaranteeing compliance with a safety limit on the optical power at low temperatures, which is advantageous in terms of performance; or to moderate the power at low temperature while guaranteeing an acceptable power at high temperature, which is advantageous in terms of energy consumption.

Moreover, it is easy and inexpensive to manufacture a temperature sensor near the laser diode.

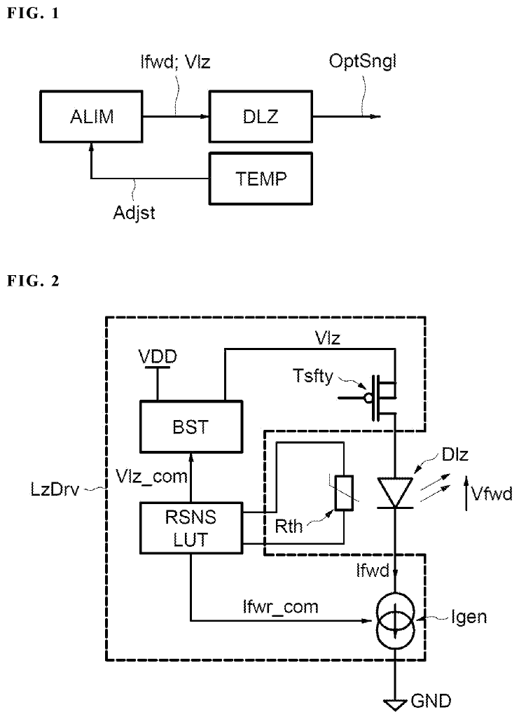

FIG. 1 illustrates a block diagram of a method for power supplying ALIM a laser diode Dlz comprising generating a power supply current Ifwd injected directly into the laser diode Dlz, and generating a power supply voltage Vlz biasing the terminals of the laser diode. The method comprises measuring the temperature TEMP near the laser diode Dlz and controlling the power supply current Ifwd at an adjusted intensity Adjst according to the measured temperature TEMP and, alternatively or in combination, controlling the power supply voltage Vlz at an adjusted level Adjst according to the measured temperature Temp.

The adjustments of the power supply current Ifwd and of the power supply voltage Vlz, are dynamically controlled during the use of the laser diode Dlz, in order to adapt the optical power of the emitted signal and the energy consumption according to the effective temperature of the laser diode operating conditions. The adjustments are for example controlled before each illumination phase comprising generation of an optical signal OptSgnl with the laser diode Dlz.

One implementation includes at least controlling the power supply current Ifwd at an adjusted intensity Adjst according to the measured temperature Temp, since this is advantageous both in terms of managing the optical power of the laser diode Dlz and in terms of energy consumption.

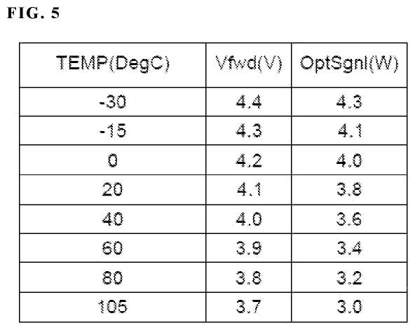

Indeed, the adjustment of the power supply current Ifwd can be made so that the optical signal OptSgnl power of the laser diode Dlz is greater at high temperatures, and the power consumption is lower at low temperatures (see below in connection with FIG. 5). Moreover, controlling the power supply voltage Vlz at an adjusted level Adjst according to the measured temperature Temp, is advantageous in terms of energy consumption (see below in relation to FIG. 5).

FIG. 2 illustrates an exemplary embodiment of a device DIS including a laser diode Dlz and a circuit for power supplying the laser diode LzDrv adapted to implement the method for power supplying the laser diode Dlz described previously in relation to FIG. 1. For example, the laser diode Dlz is of the vertical cavity surface emitting laser type “VCSEL”, and generates an optical signal OptSgnl having a linear power with respect to the forward current Ifwd circulating in the direction from the anode to the cathode of the diode. The laser diode Dlz is controlled by imposing the forward current Ifwd at its terminals, the intensity of which corresponds to the desired optical power, for example of the order of 1 A to 3 A (amperes).

The optical signal OptSgnl is usually in the infrared wavelength range, typically at 940 nm (nanometers). When the diode is controlled by the forward current Ifwd, its threshold voltage Vfwd, also called forward voltage, biases its terminals.

The power supply circuit LzDrv is thus configured to generate the power supply current Ifwd, injected directly into the laser diode, for example by means of a current generator Igen, usually including current mirror transistor assemblies, coupled between the cathode and ground GND, in order to draw the forward current Ifwd on the cathode.

The power supply circuit LzDrv is also configured to generate the power supply voltage Vlz that is capable of biasing the terminals of the laser diode Dlz, that is to say power supplying the anode voltage of the diode, for example by means of a voltage converter BST. The voltage converter BST is configured to generate the power supply voltage Vlz, for example at substantially 6.6 V (volts), from a reference power supply voltage VDD, for example at substantially 3.3 V. In various embodiments, voltage converter BST may be implemented using a linear power supply such as a linear regulator or a voltage regulator such as a low dropout (LDO) voltage regulator, or a switched-mode power supply, such as a buck converter or a boost converter.

The power supply voltage Vlz at the output of the converter BST is adjusted so that it is at least equal to the threshold voltage Vfwd of the diode Dlz, plus a margin voltage, for example from 1V to 2 V. The margin voltage is provided in order to saturate the current source Igen and a possible safety switch Tsfty on the diode supply. The margin voltage is also provided to allow a rapid rise in the current in the diode Dlz taking into account parasitic inductive elements in the circuit.

The output power of the converter BST is equal to the average current Ifwd circulating in the branch of the diode Dlz, multiplied by the output voltage Vlz of the converter BST. The threshold voltage Vfwd of the laser diode Dlz, of the VCSEL type, has variations depending on the temperature of approximately 15% to 40% between 105° C. and −30° C. (see FIG. 5 described below). The optical power emitted by the laser diode Dlz, of the VCSEL type, for a fixed current has variations according to the temperature, for example from 20% to 40% between 105° C. and −30° C. The device DIS includes in this respect a temperature sensor Rth, RSNS, mounted near the laser diode Dlz, and the power supply circuit LzDrv is configured to generate the power supply current Ifwd at an adjusted intensity according to the temperature measured, and/or to generate the power supply voltage Vlz at an adjusted level according to the measured temperature.

Thus, the power supply circuit LzDrv is configured to generate the intensity of the power supply current Ifwd adjusted for a generation of an optical signal OptSgnl at a target power by the laser diode at the measured temperature, and/or to generate the level of the power supply voltage Vlz adjusted for the threshold voltage Vfwd of the laser diode at the measured temperature.

The temperature sensor may include a conventional temperature measuring component Rth, such as a thermal resistor called a thermistor, and a read circuit RSNS. This type of thermistor component exists in a very compact box, for example, 0.2 mm (millimeters) by 0.4 mm, and the temperature can be read by injecting 100 pA (microamps) into a 10 kOhm (kiloOhms) resistor and converting the voltage at the terminals of the thermistor into a digital value. The digital value can be converted so as to form a control signal Ifwd_com, Vlz_com adapted to control the adjustment of the intensity of the power supply current Ifwd by the current generator Igen, and the adjustment of the level of the power supply voltage Vlz by the voltage converter BST. The temperature of the laser diode Dlz is thus measured indirectly via the thermistor Rth placed near the laser Dlz, that is to say as close as possible but at a non-zero distance in practice. In some embodiments, read component RSNS may include an analog-to-digital converter in order to convert an analog output of the temperature sensor to the digital domain.

In some embodiments, it may be advantageous in terms of cost not to provide an embodiment of a temperature sensor embedded in the chip of the laser diode Dlz. Indeed, lasers, in particular of the VCSEL type, are typically produced on III-V type semiconductor substrates, in particular made of gallium arsenide AsGa, which are complex and very expensive technologies. It would thus not be cost effective to consume the GaAs substrate area and steps of the method III-V for manufacturing an integrated temperature sensor. As a result, the measured temperature may not strictly reflect the temperature of the PN junction of the diode.

In order to improve the relevance of the measured temperature with respect to the actual temperature of the PN junction of the diode and the effective behavior of the laser signal, the power supply circuit LzDrv includes a temperature-intensity correspondence table look-up table (LUT) to define the adjustment of the power supply current in relation to the measured temperature. The correspondence table LUT is specifically established for each laser diode Dlz production, by measurements of the optical power emitted under different temperature conditions, correlated with the different measurements of temperature respectively obtained.

Thus, the power supply circuit LzDrv is configured to obtain the adjusted intensity of the power supply current Ifwd, communicated by the respective control signal Ifwd_com, by reading the temperature-intensity pair correspondence table LUT at the measured temperature.

Similarly, to define the adjustment of the power supply voltage Vlz, a temperature-voltage pair correspondence table LUT is specifically established for each laser diode Dlz production, by electrical characterization measurements carried out under different temperature conditions, and related to the different temperature measurements respectively obtained.

The power supply circuit LzDrv is thus configured to obtain the adjusted level of the power supply voltage Vlz, communicated by the respective control signal Vlz_com, by reading the temperature-voltage pair correspondence table LUT at the measured temperature. Thus, the correspondence tables LUT specifically established by measurements in real conditions for each laser diode Dlz production allow to benefit from appropriate and reliable adjustments of the intensity and voltage.

In various embodiments, the correspondence table LUT may be implemented using a memory that that maps the output of the temperature sensor to digital power control setting to produce control signal Vlz_com. Depending on the topology of voltage converter BST, Vlz_com may be a digital signal that controls the output voltage of voltage converter BST directly. In some embodiments, Vlz_com may be generated using a digital-to-analog converter to produce an analog voltage reference signal for voltage converter BST.

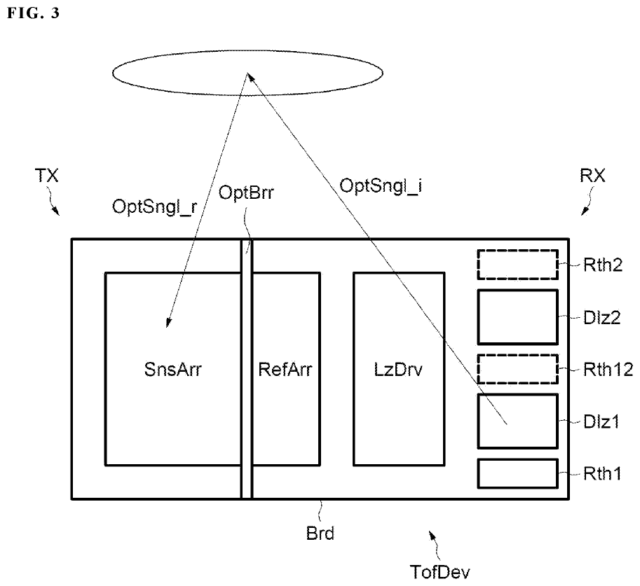

FIG. 3 illustrates a schematic view of an electronic circuit board Brd of the printed circuit type (usually “PCB” for “Printed Circuit Board”) in an example of application of a distance sensor product by time of flight TofDev.

The time-of-flight sensor TofDev includes an emitter TX and a receiver RX, and is configured to implement integration phases comprising an emission of an optical signal OptSngl_i generated by the emitter TX, and a reception of the optical signal emitted after a reflection OptSngl_r with the receiver RX. The measurement of the time shift in the received signal OptSngl_r with respect to the emitted signal OptSngl_i allows the device to deduce, knowing the speed of light, the distance between the reflection surface and the sensor. The measurement of the time shift can be obtained in practice by measuring the phase shift, in the received signal OptSgnl_r, of a modulation pattern of the emitted signal OptSgnl_i. In various embodiments, the time shift may be measured using time-of-flight time shift measurement circuits and methods known in the art. For example, in some embodiments, a time-to-digital converter (TDC) may be used to the time interval between the transmission and reception of the light pulse. The TDC can be implemented using various techniques, including Vernier delays, ring oscillators, and time amplifiers.

The emitter TX includes a device DIS for controlling a laser diode as described in relation to FIGS. 1 and 2, including in this example two laser diodes Dlz1, Dlz2, and the power supply circuit LzDrv. The emitter TX further typically includes usual electrical components, such as inductive and capacitive elements (not shown).

The power supply circuit LzDrv may include a controller configured to control the instants of emission, and to control a modulation in the emitted optical signal OptSgnl_i.

Finally, the temperature sensor Rth1 is mounted on the printed circuit board Brd, for example a solder mounting of the “SMD” type (for “Surface Mounted Device”), close to at least one of the two laser diodes Dlz1. Alternatively, or in combination, a second temperature sensor Rth2 can be mounted close to the other laser diode Dlz2. Alternatively, or in combination, a third temperature sensor Rth12 can be mounted close to the two laser diodes Dlz1, Dlz2, therebetween. Thus, the temperature near the diode can be measured before each integration phase, in order to adjust the power supply current Ifwd and the power supply voltage Vlz specifically to the conditions of each integration phase.

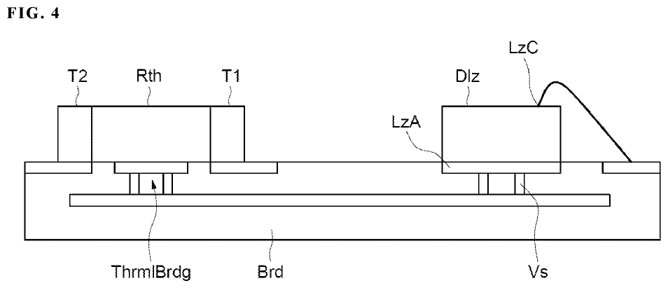

Advantageously, and as will be described below in relation to FIG. 4, the printed circuit board Brd can be provided with a thermal bridge to conduct the heat from the diode Dlz1, Dlz2 to the thermistor Rth1, Rth2, Rth12.

The receiver RX includes a photosensitive region SnsArr, RefArr, usually a network of single-photon avalanche effect diodes “SPAD”. The photosensitive region includes a part SnsArr dedicated to the detection of the received optical signal OptSngl_r and a part RefArr dedicated to the detection of the directly emitted optical signal OptSngl_i, serving as a reference for the emission instant. The part RefArr receives the emitted optical signal OptSngl_i reflected on the internal walls of an encapsulation box of the product TofDev. The part SnsArr is adapted to receive the optical signal reflected through an optical filter, and is sheltered from the emitted optical signal OptSngl_i reflected on the internal walls of the box by an optical barrier OptBrr, which is opaque, arranged inside the box.

FIG. 4 schematically illustrates a cross-sectional view of a thermal bridge ThrmlBrdg incorporated into the printed circuit board Brd. The thermal bridge ThrmlBrdg is adapted to thermally conduct the heat coming from a part in contact with the laser diode LzA towards a measurement point of the temperature sensor Rth located nearby, that is to say as close as possible but at a non-zero distance from the laser diode Dlz. In this respect, the thermal bridge ThrmlBrdg includes a metal track located in the interconnection levels of the board Brd, soldered to the anode LzA of the laser diode Dlz via metal vias Vs.

The metal track linked to the anode LzA serves two purposes: it transmits the power supply to the diode Dlz and connects the cathode LzC of the laser diode Dlz to the interconnection circuit via a solder wire. The electrical track on the surface of the board Brd is used for this purpose in this example. The metal track of the thermal bridge ThrmlBrdg is on the other hand connected to a measurement point in contact with the thermistor Rth, also by means of via.

Thus, the heat in contact with the laser diode LzA is conveyed to a measurement point of the temperature sensor, that is to say in contact with the thermistor Rth, by thermal conduction in the continuity of metals of the thermal bridge ThrmlBrdg. The metal of the metal track and of the vias can advantageously be made of copper. The metal track of the thermal bridge ThrmlBrdg is not electrically connected to the thermistor Rth. The thermistor Rth is also electrically coupled to electrical tracks on the surface of the board Brd. This improves the accuracy and relevance of temperature measurement with respect to the behavior of the laser diode, in a simple, efficient and economical way.

FIG. 5 illustrates an example table of values of the optical power OptSgnl in watts (W) that can be emitted by a laser diode power supplied with a fixed current Ifwd of X A, for example 1 A≤X A≤3 A, for temperatures TEMP ranging from −30° C. to 105° C., and the threshold voltage Vfwd in volts (V) under the same conditions.

It can be seen that, for a given current Ifwd, the optical power emitted by the VCSEL laser varies greatly with temperature, substantially by 20% to 40% between 105° C. and −30° C.; and the threshold voltage Vfwd of the diode varies from 15% to 40%.

In the example of the application to a time-of-flight sensor, the intensity of the power supply current Ifwd and the level of the power supply voltage Vlz are chosen according to this type of table to account for variations with respect to a limit imposed on the power of the optical signal OptSngl and/or on the energy consumption for an integration phase. For example, if the power of the optical signal is less than 5 W, then the power supply current Ifwd is chosen so that the maximum value of optical power in the temperature range is less than 5 W, possibly with a safety margin. The current of X A is thus sized to produce a maximum optical power at −30° C. of 4.3 W. This implies that the optical signal power at 105° C. will be of the order of 3.0 W.

On the other hand, the power supply voltage Vlz is chosen so as to support the maximum threshold value Vfwd in the temperature range, that is to say 4.4 V at −30° C., which is oversized for the minimum threshold value Vfwd in the temperature range, that is to say 3.7 V at 105° C.

However, the device DIS for controlling the laser diode Dlz described previously in relation to FIGS. 1 to 4, allows the dynamic adjustment of the power supply current Ifwd according to the temperature TEMP, so that the performance of the laser diode and/or its power consumption are substantially independent of temperature.

Thus, in accordance with embodiments, it is advantageously possible to control the intensity of the power supply current Ifwd adjusted so as to obtain a high target optical power, for example of 4.5 W, regardless of the temperature, by increasing the intensity of the current Ifwd for high temperatures. It is also possible to control the intensity of the adjusted power supply current Ifwd so as to obtain a moderate target optical power, for example of 3.7 W regardless of the temperature, by reducing the intensity of the current Ifwd for low temperatures and by increasing it for high temperatures.

On the other hand, the control for adjusting the level of the power supply voltage Vlz allows the power supply voltage Vlz to be precisely adapted to the level of the threshold voltage Vfwd at a given temperature to alleviate the problem of the oversizing of the power supply voltage at high temperatures.

Furthermore, given that the adjustments of the current Ifwd and the voltage Vlz are made with values established specifically for each practical laser diode production (by means of the correspondence tables LUT), variations in behavior may exist between several productions of the same laser diode device do not need to be taken into account to adapt the current Ifwd and the voltage Vlz to the worst cases.

Thus, in a range of temperatures, with for example a moderate target optical power, at low temperature the power supply current Ifwd has a small value in the range, and the power supply voltage Vlz has a large value in the range; while at high temperature, the power supply current Ifwd has a large value in the range, and the power supply voltage Vlz has a small value in the range.

Consequently, the energy consumption can be reduced throughout the temperature range such that the optical performance is not degraded at high temperature and safety limits are not exceeded at low temperatures.

What is claimed is:

1. A method for power supplying a laser diode comprising:
generating a power supply current injected directly into the laser diode;
generating a power supply voltage biasing terminals of the laser diode;
measuring a temperature in a vicinity of the laser diode; and
controlling the power supply current at an adjusted intensity according to the measured temperature or controlling the power supply voltage at an adjusted level according to the measured temperature.

2. The method according to claim 1, wherein the intensity of the power supply current is adjusted to generate an optical signal at a target power by the laser diode at the measured temperature.

3. The method according to claim 1, wherein the level of the power supply voltage is adjusted for a threshold voltage of the laser diode at the measured temperature.

4. The method according to claim 1, further comprising:
obtaining the adjusted intensity of the power supply current by reading a temperature-intensity pair correspondence table, wherein the intensity pair correspondence table comprises entries based on a relationship between optical power and temperature for the laser diode.

5. The method according to claim 1, wherein the adjusted level of the power supply voltage is obtained by reading a temperature-voltage pair correspondence table, wherein the temperature-voltage pair correspondence table comprises entries based on a relationship between threshold voltage and temperature for the laser diode.

6. The method according to claim 1, wherein measuring the temperature in the vicinity of the laser diode comprises providing thermal conduction between the laser diode and a temperature measurement point via a thermal bridge between the laser diode and the temperature measurement point.

7. A time-of-flight distance measurement method, comprising:
emitting an optical signal by the laser diode during an integration phase;
providing power to the laser diode according to the method of claim 1;
receiving a reflection of the optical signal emitted by the laser diode; and
measuring a time shift between emitting the optical signal and receiving the reflection.

8. A device comprising:
a laser diode;
a temperature sensor located in a vicinity of the laser diode; and
a power supply circuit for supplying power to the laser diode, the power supply circuit configured to:
generate a power supply current configured to be injected directly into the laser diode, and
generate a power supply voltage configured to bias terminals of the laser diode, wherein
the power supply circuit is configured to:
generate the power supply current at an adjusted intensity according to a temperature measured by the temperature sensor, or
generate the power supply voltage at an adjusted level according to the temperature measured by the temperature sensor.

9. The device according to claim 8, wherein the power supply circuit is configured to generate the intensity of the power supply current adjusted for a generation of an optical signal at a target power by the laser diode at the temperature measured by the temperature sensor.

10. The device according to claim 8, wherein the power supply circuit is configured to generate the level of the power supply voltage adjusted for a threshold voltage of the laser diode at the measured temperature.

11. The device according to claim 8, wherein:
the power supply circuit includes a temperature-intensity pair correspondence table, wherein the intensity pair correspondence table comprises entries based on a relationship between optical power and temperature for the laser diode; and
the power supply circuit is configured to obtain the adjusted intensity of the power supply current by reading the temperature-intensity pair correspondence table.

12. The device according claim 8, wherein:
the power supply circuit includes a temperature-voltage pair correspondence table, wherein the temperature-voltage pair correspondence table comprises entries based on a relationship between threshold voltage and temperature for the laser diode; and
the power supply circuit is configured to obtain the adjusted level of the power supply voltage by reading the temperature-voltage pair correspondence table.

13. The device according to claim 8, wherein the temperature sensor includes a thermal bridge configured to thermally conduct heat in contact with the laser diode towards a measurement point of the temperature sensor near the laser diode.

14. A time-of-flight distance sensor, comprising:
an emitter comprising the device according to claim 8; and
an optical receiver, wherein the time-of-flight distance sensor is configured to, during an integration phase:
emit an optical signal using the laser diode,
receive a reflection of the optical signal emitted by the laser diode, and
measure a time shift in the received reflection with respect to the emitted optical signal.

15. A time-of-flight distance sensor, comprising:
a printed circuit board (PCB);
a laser diode disposed on the PCB;
a temperature sensor disposed on the PCB and thermally coupled to the laser diode through the PCB via a thermal bridge; and
a power supply disposed on the PCB an electrically coupled to the laser diode and the temperature sensor, the power supply configured to adjust a power level provided from the power supply to the laser diode based on temperature measurement provided by the temperature sensor, the adjusted power level configured to cause the laser diode to provide an optical signal at a target power.

16. The time-of-flight distance sensor of claim 15, wherein the power supply comprises:
an adjustable current source having an output connected to a first terminal of the laser diode; and
a voltage output connected to a second terminal of the laser diode.

17. The time-of-flight distance sensor of claim 16, wherein the power supply is configured to adjust the power level of the power supply by adjusting a voltage of the voltage output based on the temperature measurement and the target power.

18. The time-of-flight distance sensor of claim 16, wherein the power supply is configured to adjust the power level of the power supply by adjusting a current provided by the adjustable current source based on the temperature measurement and the target power.

19. The time-of-flight distance sensor of claim 15, further comprising:
an optical receiver disposed on the PCB; and
a time-measurement circuit configured to measure a time delay between a transmission of a light pulse from the laser diode to a reception of a reflection of the light pulse by the optical receiver.

20. The time-of-flight distance sensor of claim 19, wherein the optical receiver comprises an array of single-photon avalanche diodes (SPAD).
